(19) United States
(12) Patent Application Publication
(10) Pub. No.: US 2005/0170638 A1
(43) Pub. Date: Aug. 4, 2005

(54) Method for forming dual damascene interconnect structure

(76) Inventors: Bang-Ching Ho, Hsinchu (TW); Jian-Hong Chen, Hsin-Chu (TW)

Correspondence Address: DUANE MORRIS, LLP;IP DEPARTMENT, ONE LIBERTY PLACE, PHILADELPHIA, PA, 19103-7396, US

(21) Appl. No.: 10/768,217

(22) Filed: Jan. 30, 2004

(51) Int. Cl. H01L 21/4763; H01L 21/44

(52) U.S. Cl. 438/629; 438/638; 438/637; 438/631; 438/633; 438/622

(57) ABSTRACT

A method for forming dual damascene structures within a semiconductor device utilizes a plug material that is soluble in alkaline developers such as 2.38 wt % TMAH. The plug material is introduced into openings initially formed in a dielectric film and extends up to at least the top surface of the dielectric film. The plug material is polymeric in nature and is baked to cross link the polymeric material. The dielectric layer with openings filled with the cross-linked plugged material is patterned and etched to produce dual damascene openings.

### BACKGROUND OF THE INVENTION

In today's rapidly advancing semiconductor manufacturing industry, dual damascene interconnect features are advantageously used to provide planarized interconnect structures that afford the use of multiple interconnect layers and therefore increase levels of device integration. Dual damascene interconnect features are typically formed by forming an initial opening in a dielectric film, then forming a pattern with a wider opening over the existing opening, and etching to form a two-tiered or dual-damascene opening within the dielectric film. The dual-damascene opening is then filled with a conductive material and planarized.

After the initial openings are formed in the dielectric layer, a photoresist pattern is formed over the layer, patterned and etched to produce the dual-damascene feature. Because of problems associated with patterning the photoresist and etching the previously etched dielectric layer, anti-reflective coatings such as bottom anti-reflective coatings (BARC) and plug materials recessed below the top surface of the dielectric layer, have been used to address the issues of pattern distortion, “fencing” and photoresist poisoning. A method for utilizing a plug material recessed below the top surface of the dielectric layer is provided in U.S. Pat. No. 6,488,509, entitled Plug Filling for Dual Damascene Process, issued Dec. 3, 2002, the contents of which are incorporated by reference as if set forth in their entirety. Employing a plug material that is receded below the top surface of the dielectric layer, however, still produces varying thicknesses of the photoresist formed over the topography and varying reflectivity. Photoresist poisoning is yet another shortcoming associated with this technique.

A process for planarizing the plug material to avoid the aforementioned problems is provided in U.S. Pat. No. 6,458,705, entitled Method for Forming Via-First Dual Damascene Interconnect Structure, issued Oct. 1, 2002, the contents of which are hereby incorporated by reference as if set forth in their entirety. U.S. Pat. No. 6,458,705 provides for planarizing the plug material using chemical mechanical polishing (CMP) in conjunction with an additional BARC layer. This process sequence introduces additional processing costs, the potential for increased particle generation and film loss during the developing process used to develop the plug material, and may further result in fencing problems if the height of plug material is too high and/or if the photoresist etch rate is too low.

What is needed, therefore, is a method and structure for dual damascene technology without the aforementioned shortcomings.

### SUMMARY OF THE INVENTION

To achieve these and other objects and in view of its purposes, the present invention addresses the shortcomings of conventional dual damascene technology and provides a method and structure for forming dual damascene structures.

In one exemplary embodiment, the present invention provides a method for forming a semiconductor device. The method includes providing a substrate with a film having a top surface and forming a opening in the film, the opening extending down from the top surface. The method further provides for introducing a plug material onto the substrate and to a level not below the top surface. The plug material is disposed within the opening and soluble in an alkaline developing solution. The method further provides for baking the plug material to cross-link the plug material and forming a photoresist layer over the top surface. The photoresist layer may be used as a mask to further pattern the film, such as to form a dual damascene structure within the film.

In another embodiment, the present invention provides a semiconductor device having a photoresist film formed over a substantially planar upper surface of a semiconductor substructure. The substructure includes a dielectric film having a top surface and an opening extending downward from the top surface, the opening filled with a substantially cross-linked form of a plug material that extends up to at least the top surface.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing. Included in the drawing are the following figures, each of which is a cross-sectional view:

FIG. 1 shows a photoresist pattern formed over a dielectric layer as in the PRIOR ART;

FIG. 2 shows a plurality of openings formed in the dielectric layer as according to the PRIOR ART;

FIG. 3 shows a plug material of the present invention formed over the structure shown in FIG. 2 including within the openings;

FIGS. 4A-1 through 4A-4 show an exemplary sequence for forming dual damascene openings according to the present invention;

FIGS. 4B-1 through 4B-5 show another exemplary sequence for forming dual damascene openings according to the present invention; and

FIG. 5 shows an exemplary dual damascene interconnect structure formed by the present invention.

### DETAILED DESCRIPTION

The present invention provides a method for forming a dual damascene interconnect structure using a polymeric plug material that includes a hydroxyl group or a carboxyl group, and a cross-link component. The plug material is soluble in alkaline developers such as TMAH (tetramethyl ammonium hydroxide). The plug material is introduced over a dielectric layer and into openings formed within the dielectric layer. A controlled develop process is used to recede an original top surface of the plug material to a level at or above the top surface of the dielectric layer. After develop, the structure includes a substantially planar upper surface. The plug material is then baked to cross-link the polymeric material, then a photoresist pattern is formed over the planar upper surface and an etching procedure is carried out. The etching procedure may be used to produce a dual damascene structure.

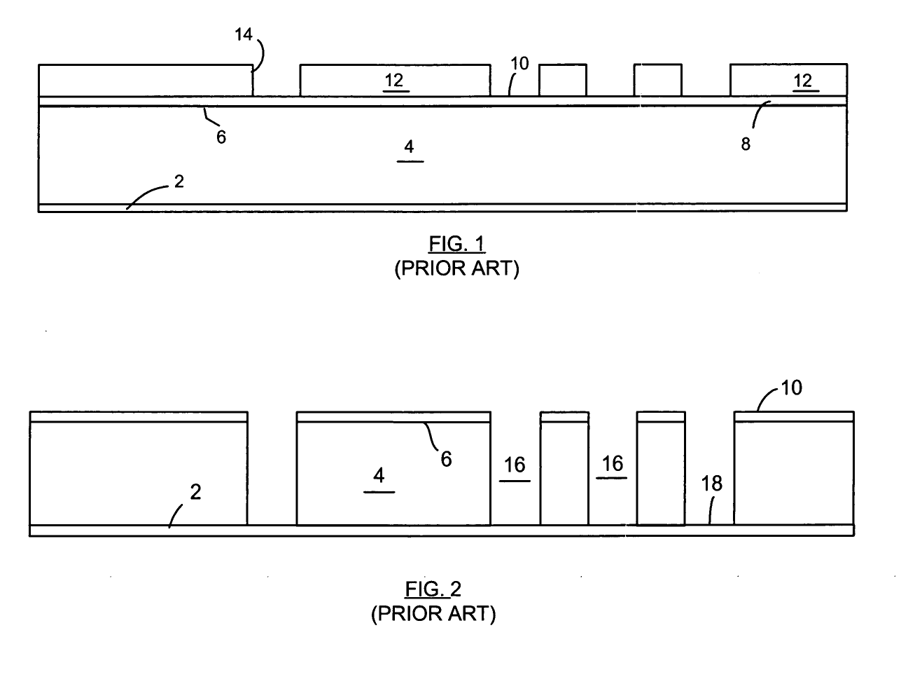

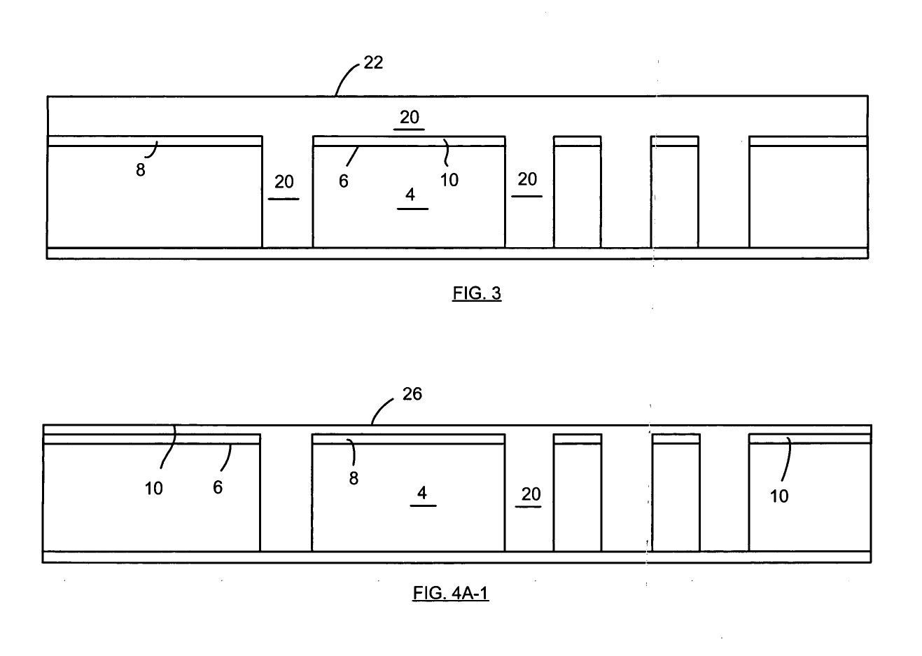

Now referring to the figures, FIG. 1 is a cross-sectional view showing dielectric layer 4 formed over bottom layer 2. Bottom layer 2 may be a semiconductor substrate, a conductive layer, or any of various layers used in the manufacture of various semiconductor devices. In one exemplary embodiment, bottom layer 2 may be a stop (i.e. etch stop) layer such as SiN or SiC or it may be a further dielectric. Dielectric layer 4 includes top surface 6. Dielectric layer 4 may be an oxide, a low-k dielectric film, or any of various suitable dielectric materials used in the formation of semiconductor devices. In one exemplary embodiment, dielectric layer 4 may include multiple films. Disposed over dielectric layer 4 is optional thin film 8. Thin film 8 may be an anti-reflective coating (ARC) or a hard mask and may be formed of inorganic materials such as SiON, SiOC, SiN, TaN or any of various other suitable materials that may be used as anti-reflective coatings and/or hard masks. Thin film 8 includes top surface 10. Patterned photoresist layer 12 is formed over top surface 10 and includes PR openings 14. Various suitable photoresists are conventionally available and may be used.

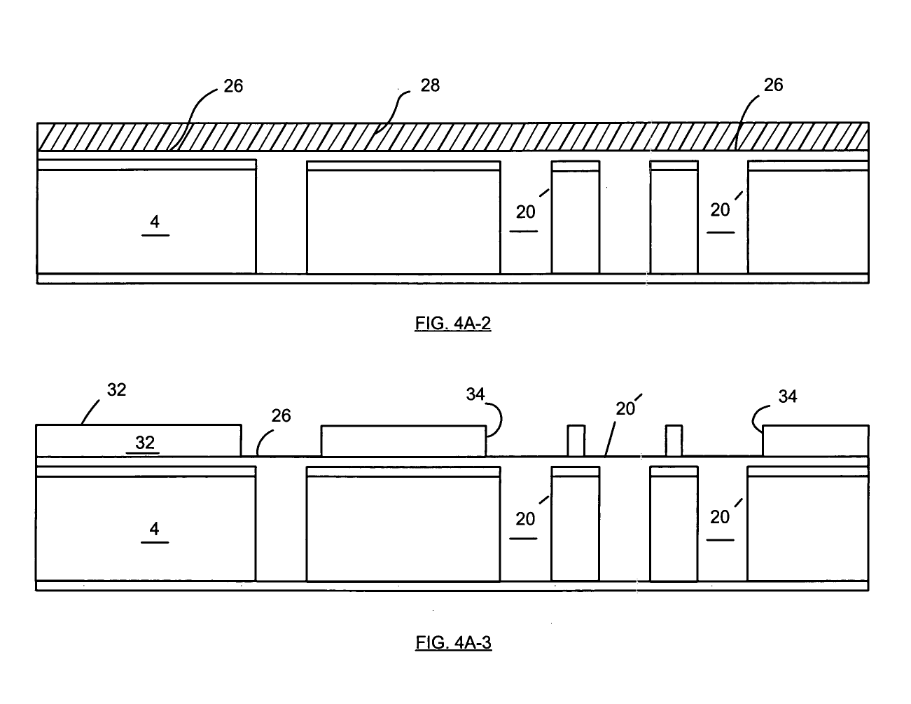

FIG. 2 shows the structure shown in FIG. 1 after an etching process has been used to form openings 16 in dielectric layer 4 and after the photoresist shown in FIG. 1 has been removed. Conventional etching and photoresist removal procedures may be used. Openings 16 each include bottom surface 18 and extend downward from top surface 6 and through optional thin film 8 and dielectric layer 6.

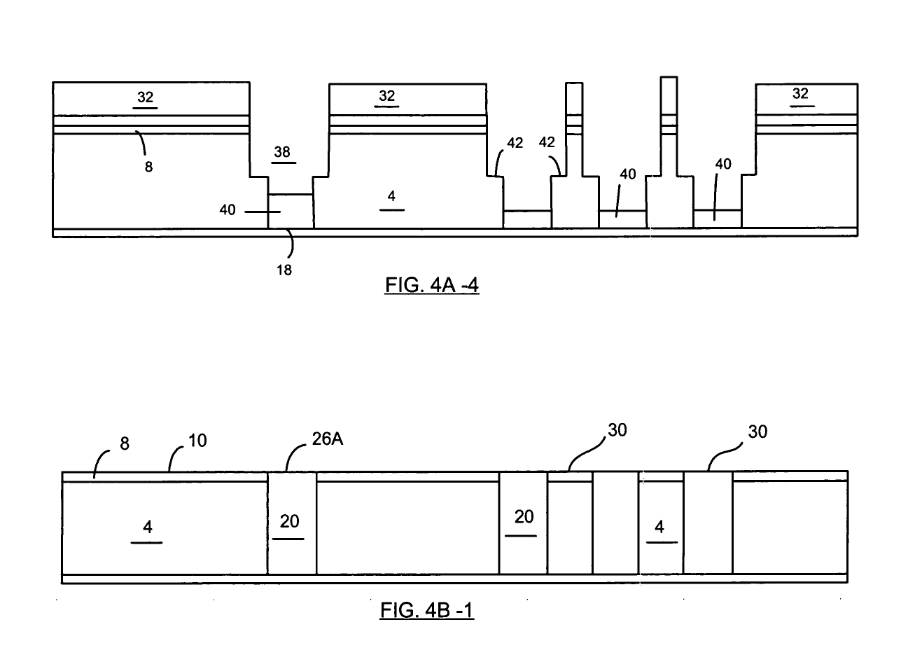

Plug material 20 is then introduced over top surface 10 (and over top surface 6) and also fills openings 16 formed within dielectric layer 4 as show on FIG. 3. Plug material 20 includes top surface 22 as formed. Conventional spin-coating processes may be used to form plug material 20 within openings 16 and over top surface 10. Plug material 20 is soluble in an alkaline developer solution. For example, plug material 20 may be developed by a developer such as 2.38 wt % TMAH. Other alkaline developers may be used in other exemplary embodiments. Plug material 20 may be chosen to include an alkali dissolution speed of about 3 to 200 nanometers per second in about 0.1% to 20% alkali aqueous solution, but other dissolution speeds may be used in other exemplary embodiments. Plug material 20 preferably includes a hydroxyl group or a carboxyl group and a cross linking component. Plug material 20 may be a polymer containing a repeating unit having a hydroxyl group or a carboxyl group on its main chain or plug material 20 may be a polymer containing a repeating unit having a hydroxyl group or a carboxyl group on its side chain. In various exemplary embodiments, the polymer may include acrylic acid, methacrylic acid, acrylic acid hydroxyalkyl ester, methacrylic acid, hydroxylalkyl ester, or hyrdroxystyrene as a repeating unit. In one advantageous embodiment, the polymer may be void of aromatic rings. Plug material 20 may include a polymer having a weight-average molecular weight within the range of 500 to 30,000, but other molecular weights may be used in other exemplary embodiments. Various suitable cross-linking components may be used and in one embodiment at least two cross-linking groups may be used. According to various exemplary embodiments, an alkali dissolution speed adjusting compound may be added to adjust the dissolution/developing speed of the plug material in the corresponding developer.

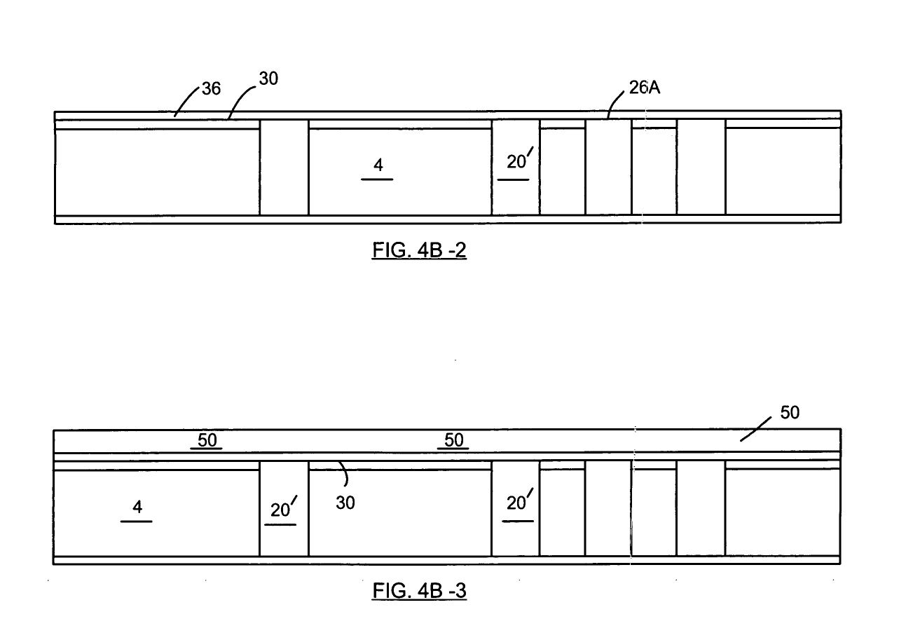

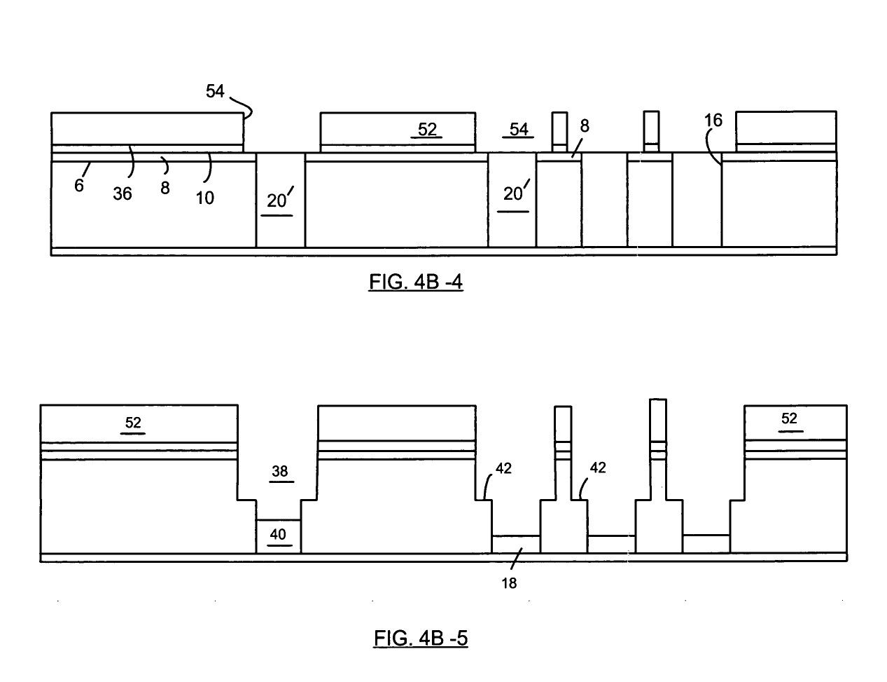

After plug material 20 is formed within openings 16 and over top surface 10 as shown in FIG. 3, a controlled develop process is used to recede upper surface 22 of plug material 20 to a desired level lower than its original level, but not below top surface 10 or top surface 6. FIGS. 4A-1 and 4B-1 illustrate two embodiments of structures with different levels of receded surface 26, that may be produced. A controlled and timed develop process using an alkaline developer such as 2.3 weight percent TMAH may be used to produce the structures shown in FIGS. 4A-1 and 4B-1 in which the receded surface 26 of plug material 20 is at a level not below top surface 6 of dielectric layer 4.

FIG. 4A-1 shows an exemplary embodiment in which receded surface 26 of plug material 20 is a continuous surface and plug material 20 includes portions over top surface 10 and top surface 6 of dielectric layer 4. Receded surface 26 of plug material 20 is substantially planar. In another exemplary embodiment (not shown) in which optional thin film 8 is not present, the develop time and conditions may be chosen so that a film of plug material 20 remains above top surface of dielectric layer 4 and includes a substantially planar top surface above top surface 6. After a develop process forms the structure shown in FIG. 4A-1, a baking process is used to cross-link plug material 20 and form cross-linked plug material 20′. Conventional methods for baking in an ambient environment may be used. A high bake temperature, such as within the range of 130° C. to 250° C. may be used. The cross-linking of the plug material prevents the plug material from mixing with photoresist films used in subsequent operations and from being developed during such processes which may be used to develop such photoresist films formed over cross-linked plug material 20′.

After plug material 20 has been cross-linked to form cross-linked plug material 20′, further resist film 28 is formed over recessed surface 26 of cross-linked plug material 20′ as shown in FIG. 4A-2. Conventional photoresist films may be used.

FIG. 4A-3 shows the structure shown in FIG. 4A-2, after photoresist film 28 of FIG. 4A-2 has been patterned, i.e., developed to form patterned for photoresist film 32 which includes openings 34. In order to form a dual-damascene structure, openings 34 are advantageously formed over openings 16 and include a width that is greater than the width of corresponding opening 16. Conventional photoresists and developers, such as alkaline developers, may be used. The developed photoresist pattern exposes portions of receded surface 26 of cross-linked plug material 20′.

An etching process is then carried out to form dual damascene openings as shown in FIG. 4A-4. Various suitable etching methods are available in the art and may be used to etch optional thin film 8, when present as in the illustrated embodiment, and dielectric layer 4. Reactive ion etching or other dry or plasma etching techniques may be used. Patterned photoresist 32 of FIG. 4A-3 serves as a mask and enables dual damascene openings 38 to be formed. Dual damascene openings 38 include terraces 42. Unetched portions 40 of cross-linked plug material 20′ remain over bottom surface 18 and within openings 38. The amount of unetched plug material 40 that remains within dual damascene opening 38 will vary depending on the relative etch rate between the cross linked plug material and the dielectric layer in the particular etching process used. In one exemplary embodiment, the relative etch rate of cross linked plug material 20′ and dielectric film 4 may be 0.9 to 1.2 and in other exemplary embodiments a relative etch rate ranging from 0.8 to 1.7 may be used. If the etch rates of the materials are the same in the etch process used to form the dual damascene opening, then unetched portion 40 may extend up to terraces 42. Since unetched portion 40 remains over bottom surface 18, bottom surface 18 is protected from harm during the etching process.

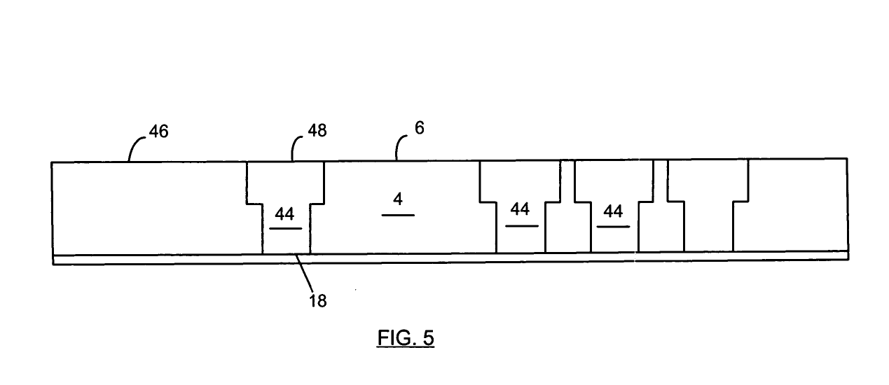

After the dual damascene openings 38 are formed as shown in FIG. 4A-4, the plug material and photoresists are stripped using conventional methods and thin film 8 removed to produce dual damascene openings 38 which may then be filled with a conductive material. The substrate may then be polished using CMP for example, to form the structure shown in FIG. 5 which includes planar top surface 46 formed of top surface 6 of dielectric layer 4 and respective top surfaces 48 of conductive materials 44 formed within dual damascene openings 38.

Now turning to the process sequence shown in FIGS. 4B-1 through 4B-5, the structure shown in FIG. 3 may be developed to form substantially planar surface 30 which consists of top surface 10 and recessed surfaces 26A of respective plug materials 20 formed within openings 16. Recessed surfaces 26A extend above top surface 6 and are level with top surface 10. In the absence of optional thin film 8, the develop conditions and time may be used to produce a planar surface formed of recessed surfaces 26A that are substantially the same level as top surface 6 of dielectric layer 4.

At this stage, plug material 20 may be baked as discussed in conjunction with FIGS. 4A-1 and 4A-2, to produce cross-linked plug material 20′.

FIG. 4B-2 shows bottom anti-reflective coating (BARC) 36 formed over substantially planar surface 30 including over recessed surfaces 26A of cross linked plug material 20′. Various BARC materials may be used and various conventional techniques may be used to perform BARC 36.

Now turning to FIG. 4B-3, photoresist film 50 is formed over BARC 36. Various suitable photoresists may be used such as photoresists that are developed in alkaline developers. The photoresist is patterned and patterned photoresist layer 52 includes PR openings 54 that expose portions of BARC 36. BARC 36 may be etched using conventional techniques to produce the structure shown in FIG. 4B-4 which includes exposed portions of thin film 8 and cross-linked plug material 20′ that resides in openings 16. Openings 54 are aligned over openings 14 and include a wider width than openings 16 to afford the formation of a dual damascene structure.

FIG. 4B-5 shows the structure of FIG. 4B-4 after a conventional etching process is used to form dual damascene openings 38 including terraces 42, in dielectric layer 4. Unetched portions 40 of cross linked plug material remain within dual damascene openings 38 and over bottom surfaces 18, to an extent determined by the relative etch rate between the cross linked plug material 20′ and dielectric layer 4 in the etch conditions used. The structure shown in FIG. 4B-5 may then have patterned photoresist 52, BARC 36 and optional thin film layer 8 removed, and a conductive material formed within dual damascene openings 38 and then polished, to form the structure shown in FIG. 5 and previously described.

The preceding merely illustrates the principles of the invention. It will thus be appreciated that those skilled in the art will be able to devise various arrangements which, although not explicitly described or shown herein, embody the principals of the invention and are included within its spirit and scope. Furthermore, all examples and conditional language recited herein are principally intended expressly to be only for pedagogical purposes and to aid the reader in understanding the principals of the invention and the concepts contributed by the inventors to furthering the art, and are to be construed as being without limitation to such specifically recited examples and conditions. Moreover, all statements herein reciting principals, aspects, and embodiments of the invention, as well as specific examples thereof, are intended to encompass both structural and functional equivalents thereof. Additionally, it is intended that such equivalents include both currently known equivalents such as equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

1. A method for forming a semiconductor device comprising:
providing a substrate with a film having a top surface formed thereover;
forming an opening in said film, said opening extending down from said top surface;
introducing a plug material onto said substrate and to a level not below said top surface, said plug material disposed within said opening and soluble in an alkaline developing solution;
baking said plug material; and
forming a photoresist layer over said top surface.

2. The method as in claim 1, further comprising patterning said photoresist layer to produce a patterned photoresist layer, and etching said film using said patterned photoresist layer as a mask.

3. The method as in claim 2, wherein said patterning includes forming a wider opening in said patterned photoresist layer over said opening, and said etching produces a dual damascene structure.

4. The method as in claim 1, wherein said introducing comprises forming said plug material within said opening and over said top surface and developing said plug material in an alkaline developing solution to recede said plug material to said level not below said top surface.

5. The method as in claim 4, wherein said developing is carried out for a time chosen to form a substantially planar surface including said plug material and said top surface.

6. The method as in claim 4, wherein said developing is carried out for a time chosen to produce said plug material having a substantially continuous upper surface including portions over said top surface.

7. The method as in claim 4, wherein said developing is carried out using a developer of about 2.38 wt % tetra methyl ammonium hydroxide (TMAH).

8. The method as in claim 1, wherein said introducing comprises forming a substantially planar surface including said top surface and a substantially co-planar upper surface of said plug material, and
further comprising forming an anti-reflective coating over said substantially planar surface, and
wherein said forming a photoresist layer comprises forming said photoresist layer on said anti-reflective coating.

9. The method as in claim 1, wherein said introducing includes forming said plug material over said top surface and within said opening, said plug material having a planar upper surface, and said forming a photoresist layer includes forming said photoresist layer over said planar upper surface.

10. The method as in claim 1, wherein said plug material is polymeric and said baking converts said plug material to a cross-linked plug material.

11. The method as in claim 10, wherein said cross-linked plug material includes a rate-average molecular weight within the range of 500 to 30,000.

12. The method as in claim 1, wherein said plug material is formed of a polymer having a cross-link component and at least one of a hydroxyl group and a carboxyl group.

13. The method as in claim 1, wherein said plug material comprises a polymer containing a repeating unit having a hydroxyl group or a carboxyl group on its main chain or its side chain.

14. The method as in claim 1, wherein said plug material comprises a polymer containing at least one of acrylic acid, methacrylic acid, acrylic acid hydroxyalkyl ester, methacrylic acid hydroxyalkyl ester, and hydroxystyrene as a repeating unit thereof.

15. The method as in claim 1, wherein said plug material has an alkali dissolution speed ranging from 3 to 200 nm/sec in a 0.1% to 20% alkali aqueous solution.

16. A semiconductor device comprising a photoresist film formed over a substrate having a substantially planar upper surface, said substrate comprising a dielectric film having a top surface and an opening extending downward therefrom, said opening filled with a substantially cross-linked form of a plug material that extends up to at least said top surface.

17. The semiconductor device as in claim 16, wherein said plug material extends up to said top surface, said top surface and said plug material combining to produce said substantially planar upper surface, and
further comprising an anti-reflective coating disposed over said substantially planar upper surface, and
wherein said photoresist film is disposed on said anti-reflective coating.

18. The semiconductor device as in claim 16, wherein said plug material is further formed over said top surface and includes a substantially planar plug material upper surface, said photosensitive film formed on said substantially planar plug material upper surface.

19. The semiconductor device as in claim 16, wherein a non-cross-linked form of said plug material is soluble in an alkaline developer solution.

20. The semiconductor device as in claim 16, wherein said plug material has an alkali dissolution speed ranging from 3 to 200 nm/sec in a 0.1% to 20% alkali aqueous solution.

21. The semiconductor device as in claim 16, wherein said cross-linked form of said plug material includes a rate-average molecular weight within the range of 500 to 30,000.

22. The semiconductor device as in claim 16, wherein said plug material comprises a polymer containing a repeating unit having a hydroxyl group or a carboxyl group on its main chain and a cross-link component.

23. The semiconductor device as in claim 16, wherein said plug material comprises a polymer containing a repeating unit having a hydroxyl group or a carboxyl group on its side chain.

24. The semiconductor device as in claim 16, wherein said plug material comprises a polymer containing at least one of acrylic acid, methacrylic acid, acrylic acid hydroxyalkyl ester, methacrylic acid hydroxyalkyl ester, and hydroxystyrene, as a repeating unit thereof.
